(19) United States
(12) Patent Application Publication
(10) Pub. No.: US 2001/0001238 A1
(43) Pub. Date: May 17, 2001

(54) Keyboard with function of examing user's physical condition

(76) Inventor: Benison Pin, Taipei Hsien (TW)

Correspondence Address: Rosenberg, Klein & Bilker, Suite 101, 3458 Ellicott Center Drive, Ellicott City, MD, 21043, US

(21) Appl. No.: 09/725,230

(22) Filed: Nov. 29, 2000

Related U.S. Application Data
(63) Continuation-in-part of application No. 09/215,540, filed on Dec. 18, 1998.

(51) Int. Cl. H03M 11/00; H03K 17/94; G08B 23/00

(52) U.S. Cl. 341/27; 341/34; 340/573.7

(57) ABSTRACT

A keyboard 11 with the function of examining user's physical condition to make a computer 12 to be able of generating a message for reminding the user of his (her) physical condition. The keyboard comprises a plurality of keys 111, a sensing unit 112, wherein the sensing unit 112 senses keystrokes of the keys 111 and produces corresponding physical parameters, whereby the computer 12 generates the message according to the physical parameters. The keyboard 11 will make the computer 12 to be able of alarming the users when their keystroke count, rate, or force exceed a corresponding predetermined threshold.

### FIELD OF THE INVENTION

1. The present invention relates to a keyboard with the function of examining user's physical condition, especially for a computer which can detect the physical parameters of users such as keystroke count, rate, and force, whereby the expert system built in the computer can give advice to the users with reference to the physical parameters to modify their individual habits of using keyboard for avoiding unnecessary physical hurt.

### BACKGROUND OF THE INVENTION

2. The nowadays keyboards have not been provided with function or means detecting the physical condition of users, the users may have typing-related injure such as injure of elbow or joint if the keystroke force or rate is not uniform. Especially, when user is focusing on typing a large document.

3. It is an object of the present invention to provide a keyboard with function of detecting user's physical condition which accompanies with the operation of a corresponding application program in a computer can make users knowing relative information of their physical condition directly form the monitor when they are using the keyboards, avoiding physical hurt through an alarm message triggered by an anomalous using and then preserving the user's health.

4. It is another object of the present invention to provide a keyboard which can display the keystroke count, rate, and force of user through a liquid crystal display (LCD).

5. The various objects and advantages of the present invention will be more readily understood from the following detailed description when read in conjugated with the appended drawing, in which:

### BRIEF DESCRIPTION OF DRAWING

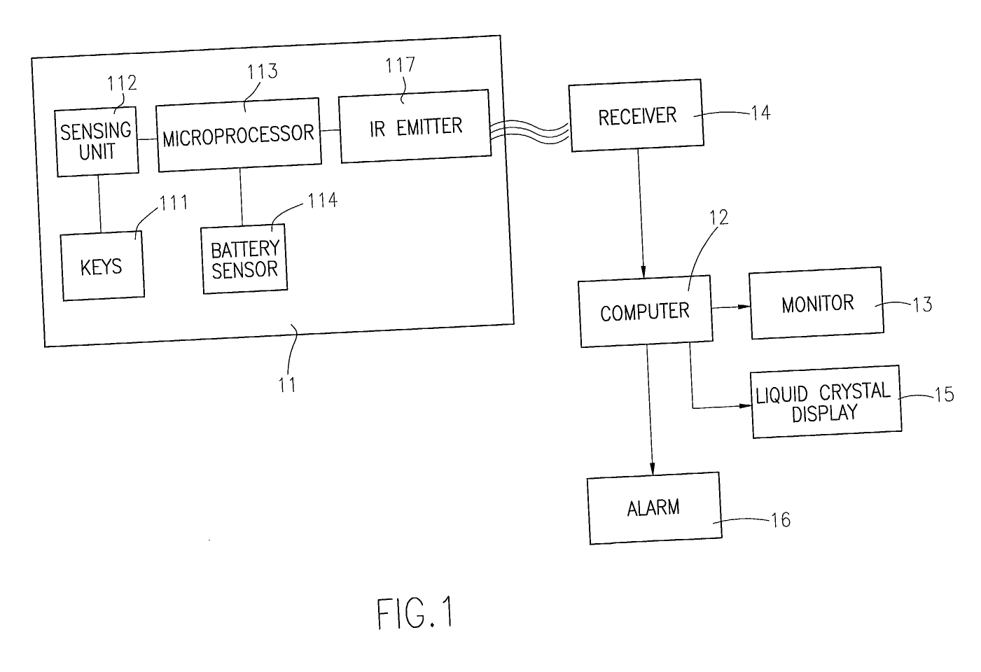

6. FIG. 1 is the schematic diagram of the invention.

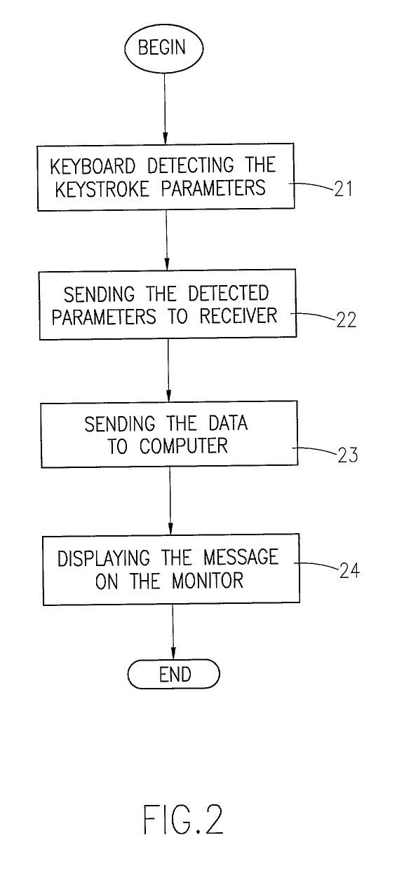

7. FIG. 2 is the flowchart of the present invention.

### DETAIL DESCRIPTION OF PREFERRED EMBODIMENT

8. As shown in FIG. 1, the inventive keyboard 11 comprises keys 111, a sensing unit 112, a microprocessor 113, a battery sensor 114, an infrared (IR) emitter 117, and a scan matrix (not shown). The user's physical parameters such as keystroke force, rate, and count are detected by sensing unit 112 and transmitted through the IR emitter 117. The sensing unit 112 may comprise a pressure detector for detecting keystroke force. The sensing unit may comprise a counter for accumulating keystroke count. The sensing unit may comprise a timer and an arithmetic unit for calculating keystroke rate.

9. The receiver 14 receives the signal transmitted from the IR emitter 117 and sends the corresponding electrical signal to the computer 12, which has a corresponding means (program) to process the corresponding electrical signal. The computer 12 is connected to a monitor 13, an LCD 15, and an alarm 16.

10. As shown in FIG. 2, this figure shows the flowchart of the present invention. In step 21, through keying the keys 111, the sensing unit 112 in the keyboard 11 senses the physical parameters of users such as keystroke count, rate, and force. In step 22, the IR emitter 117 in the keyboard 11 transmits the signal containing those parameters to the receiver 14. In step 23, the receiver 14 sends the corresponding electrical signal to the computer 12 for recording those parameters. In step 24, the computer 12 processes the corresponding signal, records those parameters, and shows those parameters on a monitor 13.

11. Moreover, if the sensing unit 112 detects that keystroke count, rate, or force exceeds a respective predetermined threshold, the corresponding program stored in the computer 12 generates an alarm signal through the alarm 16 or display a warning message on LCD 15. The user is advised to take proper gesture to prevent injure.

12. To sum up, the present invention enable a keyboard to have function of checking user's physical condition and give user advice with reference to the detecting parameters and the data of expert system or doctor. Therefore, injure of user's hand due to improper use of keyboard can be prevented.

13. Although, the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

I claim:

1. A keyboard with the function of examining user's physical condition to make a computer to be able of generating a message for reminding the user of his physical condition, and comprising:
a plurality of keys;
a sensing unit for sensing keystrokes of the keys and producing physical parameters, whereby the computer generates the message according to the physical parameters.

2. The keyboard with the function of examining user's condition as in claim 1, further comprising an infrared emitter for wireless transmitting the physical parameters from the keyboard to the computer.

3. The keyboard with the function of examining user's condition as in claim 1, wherein the sensing unit senses force of the keystrokes of the keys and the physical parameters are keystroke force.

4. The keyboard with the function of examining user's condition as in claim 1, wherein the sensing unit senses count of the keystrokes of the keys and the physical parameters are keystroke count.

5. The keyboard with the function of examining user's condition as in claim 1, wherein the sensing unit senses rate of the keystrokes of the keys and the physical parameters are keystroke rate.

6. The keyboard with the function of examining user's condition as in claim 1, wherein the computer has a liquid crystal display for displaying the message.

7. The keyboard with the function of examining user's condition as in claim 1, wherein the computer has a alarm for sounding the message.

8. The keyboard with the function of examining user's condition as in claim 1, wherein the computer generates the message if the physical parameters exceed a respective predetermined threshold.
